(19) United States
(12) Patent Application Publication
(10) Pub. No.: US 2025/0240894 A1
(43) Pub. Date: Jul. 24, 2025

(54) DISPLAY DEVICE

(71) Applicant: LG Display Co., Ltd., Seoul (KR)

(72) Inventor: Jicheol SON, Hanam-si (KR)

(73) Assignee: LG Display Co., Ltd., Seoul (KR)

(21) Appl. No.: 19/006,856

(22) Filed: Dec. 31, 2024

(30) Foreign Application Priority Data
Jan. 24, 2024 (KR) 10-2024-0011240

(51) Int. Cl. H05K 1/18; H05K 9/00

(52) U.S. Cl. CPC H05K 1/189; H05K 9/0054; H05K 2201/10128

(57) ABSTRACT

A display device is provided in which an increase in a repulsion force to bending of a flexible printed circuit board (FPC) connected to a display panel is prevented, thereby satisfying a floating thickness specification of the FPC and thus enabling the slimming of the display device. To this end, the display device can include a display panel, a cover member disposed on a front surface of the display panel; a plate disposed on a rear surface of the display panel, a bracket disposed on a rear surface of the plate so as to support the plate, a FPC having one end disposed on one end of the front surface of the display panel. The FPC is bent so that the other end thereof is disposed on a rear surface of the bracket.

### CROSS-REFERENCE TO RELATED APPLICATION

This application claims priority to Korean Patent Application No. 10-2024-0011240, filed on Jan. 24, 2024 in the Korean Intellectual Property Office, the entire contents of which is hereby expressly incorporated by reference into the present application.

### BACKGROUND

### Field

The present disclosure relates to a display device that reduces an effect of a component thickness to achieve a slim display device.

### Discussion of the Related Art

A flat panel display device includes a LCD (Liquid Crystal Display) device, a FED (Field Emission Display) device, a PDP (plasma display panel) device, and an electroluminescence display device.

An example of the electroluminescence display device includes an active matrix type organic light-emitting display device (hereinafter referred to as an OLED display device) which is commercially available. Because the OLED display device is a self-light-emitting device, the OLED display device is free of a backlight unit (hereinafter referred to as BLU), compared to the LCD display device, and has fast response speed and wide viewing angle and thus is attracting attention as a next-generation display device.

### SUMMARY OF THE DISCLOSURE

A thickness of the display device has been reduced under various attempts to reduce the thickness.

However, there is a limit in reducing the thickness of the display device due to a thickness of a circuit component of a circuit. For example, the thickness of the display device is greater than or equal to a sum of a thickness of a display panel, a source board thickness, a set board thickness, a cover thickness, and a thickness of a space between these components.

Each of the source board and the set board has the thickness equal to a sum of a thickness of a printed circuit board (hereinafter, PCB) and thicknesses of a plurality of circuit components on the printed circuit board. The circuit components can include integrated circuit chips, resistors, capacitors, transformers, etc. The thicknesses of these circuit components increase the thickness of the display device to limit a slim design of the display device.

The PCB is connected to the display panel through a flexible printed circuit board (flexible PCB, hereinafter, FPC). In a specific model, unlike an LCD model, a width of the FPC increases with application of a touch structure, and a radius of curvature R of an arc resulting from bending of the FPC decreases due to a decrease in a thickness due to non-application of BLU, thereby increasing a repulsion force to bending.

Therefore, during a manufacturing process, after bending the PCB toward a back of the display panel, floating of the FPC occurs due to the increased repulsion force to bending of the FPC, resulting in a problem of not satisfying the customer's desired thickness specification.

In order to solve or address the above-mentioned limitation, the inventor of the present disclosure has invented a display device in which the increase in the repulsion force to bending that occurs after bending of the FPC connected to the display panel can be prevented, thereby satisfying a floating thickness specification of the FPC and thus enabling slimming of the display device.

Accordingly, a purpose of the present disclosure is to provide a display device in which a plate disposed on a rear surface of the display panel is supported by a bracket, and a flexible printed circuit board FPC is disposed on a rear surface of the bracket, and a bracket fastening plate disposed on a rear surface of the flexible printed circuit board FPC fastens the bracket.

Therefore, according to an aspect of the present disclosure, the bracket fastening plate can fasten the bracket, thereby suppressing the repulsion force to bending of the flexible printed circuit board FPC.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

One aspect of the present disclosure provides a display device comprising: a display panel including a front surface and a rear surface; a cover member disposed on the front surface of the display panel; a plate disposed on the rear surface of the display panel; a bracket disposed on a rear surface of the plate so as to support the plate; a flexible printed circuit board having one end disposed on one end of the front surface of the display panel so as to face a rear surface of the cover member, wherein the flexible printed circuit board is bent so that the other end of the flexible printed circuit board is disposed on a rear surface of the bracket; and a bracket fastening plate disposed on a rear surface of the flexible printed circuit board so as to fasten the bracket.

In accordance with some embodiments of the present disclosure, the bracket fastening plate has a constant width and a predetermined length.

In accordance with some embodiments of the present disclosure, the flexible printed circuit board includes a plurality of flexible printed circuit boards arranged in a row direction, wherein each of the plurality of flexible printed circuit boards has one end of the front surface of the display panel so as to face a rear surface of the cover member, wherein each of the plurality of flexible printed circuit boards is bent so that the other end thereof is disposed on the rear surface of the bracket, wherein the bracket fastening plate has bent protrusion s respectively formed at positions corresponding to positions between adjacent ones of the plurality of flexible printed circuit boards.

In accordance with some embodiments of the present disclosure, the bent protrusions of the bracket fastening plate are fixedly fitted respectively into gaps between adjacent ones of the plurality of flexible printed circuit boards.

In accordance with some embodiments of the present disclosure, each of the bent protrusions of the bracket fastening plate protrudes toward the front surface of the display panel, and is fixedly fitted into each of the gaps between adjacent ones of the plurality of flexible printed circuit boards.

In accordance with some embodiments of the present disclosure, the bracket fastening plate is bonded to the plurality of flexible printed circuit boards through an adhesive member.

In accordance with some embodiments of the present disclosure, the plurality of flexible printed circuit boards include first to n-th flexible printed circuit boards, wherein the bracket fastening plate extends to overlap the first flexible printed circuit board at a position corresponding to one end of the display panel to the n-th flexible printed circuit board at a position corresponding to the other end of the display panel.

In accordance with some embodiments of the present disclosure, the bracket fastening plate 110 extends by a length corresponding to a sum of lengths of the first flexible printed circuit board to the n-th flexible printed circuit board.

In accordance with some embodiments of the present disclosure, in a plan view of the display device, a dimension in a row direction of the display panel is larger than a dimension in a column direction of the display panel, wherein a dimension in a row direction of the bracket fastening plate is smaller than the dimension in the row direction of the display panel.

In accordance with some embodiments of the present disclosure, an optical adjustment layer is disposed on the front surface of the display panel and between the display panel and the cover member, wherein a second adhesive member is disposed between a front surface of the optical adjustment layer and the cover member.

The technical solutions according to an embodiment of the present disclosure are not limited to those as mentioned above. Other technical solutions not mentioned above can be clearly understood by those skilled in the art from following descriptions set forth below.

According to an embodiment of the present disclosure, during the manufacturing process, the PCB is bent toward the back of the display panel and then the bracket is fixed using the bracket fastening plate, thereby suppressing the repulsion force to the bending of the flexible printed circuit board FPC.

Accordingly, the increase in the repulsion force to the bending can suppressed, thereby satisfying the floating thickness specification of the flexible printed circuit board FPC as desired by the customer. This can allow for realizing a slimmer display device.

In the display device according to an embodiment of the present disclosure, the occurrence of the repulsion force to the bending of the flexible printed circuit board FPC can be suppressed during the manufacturing process, thereby preventing the product defect.

Therefore, according to an embodiment of the present disclosure, the product defect can be suppressed to improve a lifespan of the display device.

Furthermore, according to an embodiment of the present disclosure, the thickness of the display device can be reduced by preventing the occurrence of the repulsion force to the bending of the flexible printed circuit board FPC. Accordingly, slimming of the display device can be realized.

Furthermore, according to an embodiment of the present disclosure, the occurrence of the repulsion force to the bending of the flexible printed circuit board FPC can be prevented so that a defective signal transmission through the flexible printed circuit board FPC can be prevented, thereby improving the image display quality of each pixel.

Furthermore, according to an embodiment of the present disclosure, the image display quality of each pixel can be improved, so that the quality of the product is improved and reliability is secured, thereby implementing a narrow bezel.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a block diagram schematically showing a display device according to an embodiment of the present disclosure.

FIG. 2 is a diagram schematically showing a rear surface of a display panel before installation of a bracket fastening plate according to an embodiment of the present disclosure.

FIG. 3 is a cross-sectional view of the display panel according to an embodiment of the present disclosure, cut along a cutting line A-A in FIG. 2.

FIG. 4 is a diagram schematically showing a rear surface of a display panel after installation of a bracket fastening plate according to an embodiment of the present disclosure.

FIG. 5 is a cross-sectional view of the display panel according to an embodiment of the present disclosure, cut along a cutting line B-B in FIG. 4.

FIG. 6 is a diagram showing a shape of a bracket fastening plate according to an embodiment of the present disclosure.

FIG. 7 is a diagram showing an example in which a bracket fastening plate is disposed on a plurality of flexible printed circuit boards FPC according to an embodiment of the present disclosure.

FIG. 8 is a diagram showing a FPC suctioning process before bending a display panel according to an embodiment of the present disclosure.

FIG. 9 is a diagram showing a process of bending after suctioning a display panel and a FPC according to an embodiment of the present disclosure.

FIG. 10 is a diagram showing a process of aligning a display panel according to an embodiment of the present disclosure.

FIG. 11 is a diagram showing a process of physically bonding a first plate and a second plate to each other according to an embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to”, or “connected to” another element or layer, it can be directly on, connected to, or connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or periods, these elements, components, regions, layers and/or periods should not be limited by these terms, and may not define order or sequence. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

When an embodiment can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

It will be understood that when an element or layer is referred to as being “connected to”, or “connected to” another element or layer, it can be directly on, connected to, or connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term can be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this can include a case where the signal is transferred from the node A to the node B through another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

As used herein, the term “display apparatus” can include, in a narrow sense, a display apparatus including a liquid crystal module (LCM), an organic light-emitting diode (OLED) module, or a quantum dot (QD) module including a display panel and a driver for driving the display panel. Moreover, the display apparatus can include, in a broad sense, a laptop computer, a television, a computer monitor, an automotive device or an equipment display for a vehicle, a set electronic device, a set device or a set device including a complete product or a final product including the LCM, the OLED module, or the QD module.

Therefore, the display apparatus in accordance with the present disclosure can include, in the narrow sense, a display apparatus itself including, for example, the LCM, the OLED module, QD module, etc., and can include, in a broad sense, the set device as an application product or an end-user device including a complete product or a final product including the LCM, the OLED module, or the QD module.

Moreover, in some cases, the LCM, OLED module, or QD module composed of the display panel and the driver can be expressed as “display apparatus” in a narrow sense. The electronic device as a complete product including the LCM, OLED module or QD module can be expressed as “set” device” in a broad sense. For example, the display apparatus in the narrow sense can include a display panel such as a liquid crystal panel, an organic light-emitting display panel, or a quantum dot display panel, and a source PCB as a controller for driving the display panel. The set device in the broad sense can include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel can be of any type of the display panels such as a liquid crystal display panel, an organic light emitting diode (OLED) display panel, a quantum dot (QD) display panel, and an electroluminescent display panel, etc. The display panel used in the disclosure can be not limited to a specific display panel including a flexible substrate for the OLED display panel and an underlying back plate support structure and having a bendable bezel. Moreover, the display panel used in the display apparatus according to an embodiment of the present disclosure is not limited to a shape or a size of the display panel.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship. Further, the term “can” encompasses all the meanings and coverages of the term “may.” The term “disclosure” is interchangeably used with, or encompasses all the meanings and coverages of, the term “invention.” All the components of each display device or apparatus according to all embodiments of the present disclosure are operatively coupled and configured.

Hereinafter, embodiments of the present disclosure will be described using the attached drawings. A scale of each of components as shown in the drawings is different from an actual scale thereof for convenience of illustration, and therefore, the present disclosure not limited to the scale as shown in the drawings.

Hereinafter, a display device including the same according to an embodiment of the present disclosure will be described with reference to the drawings.

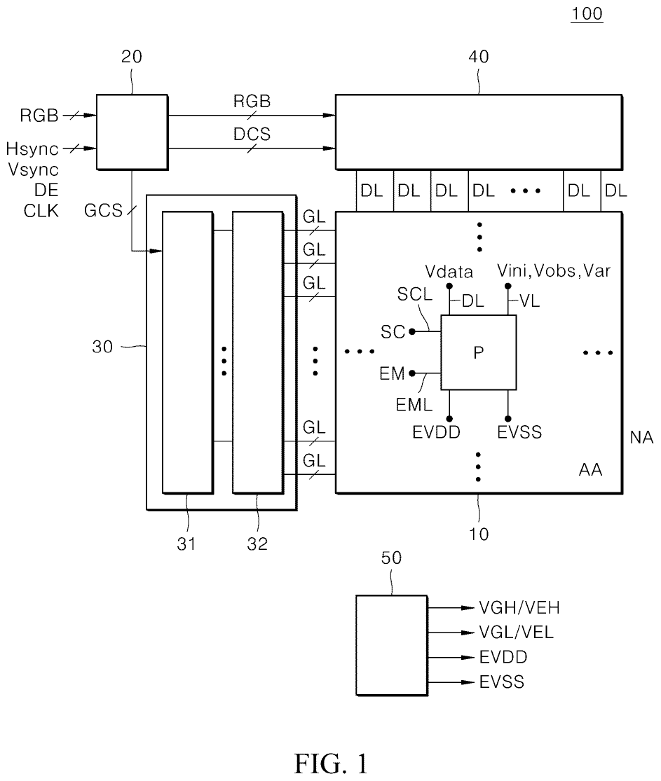

FIG. 1 is a block diagram schematically showing a display device according to an embodiment of the present disclosure.

Referring to FIG. 1, a display device 100 according to an embodiment of the present disclosure can include a display panel 10, a controller 20, a gate driver 30, a data driver 40, and a power supply 50.

The display panel 10 includes a plurality of pixels P. The display panel 10 can include a display area AA where the plurality of pixels P is located, and a non-display area NA surrounding the display area. The gate driver 30, the data driver 40, and the controller 20 are disposed in the non-display area NA. In this regard, the display area AA can include a front surface of the display panel 10, and the non-display area NA can include a rear surface 10′ of the display panel 10.

The controller 20 controls the gate driver 30 and the data driver 40. The gate driver 30 supplies a gate signal to the display panel 10. The data driver 40 supplies a data signal to the display panel 10. The power supply 50 supplies a power necessary to drive the display panel 10 thereto.

In the display panel 10, a plurality of gate lines GL and a plurality of data lines DL intersect each other, and each of the plurality of pixels P are connected to the gate line GL and the data line DL. Specifically, one pixel P receives the gate signal from the gate driver 30 through the gate line GL, and receives the data signal from the data driver 40 through the data line DL, and receives a high potential driving voltage EVDD and a low potential driving voltage EVSS from the power supply 50 through a power supply line.

In this regard, the gate line GL supplies a scan signal SC and a light-emission control signal EM to the pixel and the data line DL supplies a data voltage Vdata to the pixel. Furthermore, according to various embodiments, the gate line GL can include a plurality of scan lines SCL that supply the scan signal SC and a light-emission control signal line EML that supplies the light-emission control signal EM. Furthermore, the plurality of pixels P can additionally include a power line VL and can receive a bias voltage Vobs, an anode reset voltage Var, and an initialization voltage Vini through the power line VL.

Furthermore, each pixel P includes a light-emitting element and a pixel circuit that controls an operation of the light-emitting element. In this regard, the light-emitting element can be composed of an anode electrode AE, a cathode electrode CE, and a light-emitting layer EL disposed between the anode electrode AE and the cathode electrode CE.

The pixel circuit includes a plurality of switching elements, a driving element, and a capacitor. In this regard, each of the switching element and the driving element can be embodied as a thin-film transistor. In the pixel circuit, the driving element controls an amount of current supplied to the light-emitting element based on the data voltage to adjust an amount of light emitted from the light-emitting element. Furthermore, the plurality of switching elements receives a scan signal SC supplied through a plurality of scan lines SCL and a light-emission control signal EM supplied through a light-emission control signal line EML, and operates the pixel circuit based on the scan signal SC and the light-emission control signal EM. As used herein, the light-emission control signal EM can be simply referred to as ‘light-emission signal EM’. The light-emission control signal line EML can simply be referred to as ‘light-emission line’.

The display panel 10 can be embodied as a non-transmissive display panel or a transmissive display panel. The transmissive display panel can be applied to a transparent display device where an image is displayed on a screen and a real object in a background is visible to a viewer in front of the display device. The display panel 10 can be manufactured as a flexible display panel. The flexible display panel can be embodied as an OLED panel using a plastic substrate.

The pixels P can include a red pixel, a green pixel, and a blue pixel to emit light of corresponding colors. The pixels P can further include a white pixel. Each of the pixels P includes a pixel circuit.

Touch sensors can be disposed on the display panel 10. Touch input can be sensed using separate touch sensors or can be sensed through the pixels P. The touch sensors can be disposed on the screen of the display panel in an on-cell type or add-on type or can be embodied as in-cell type touch sensors built into the display panel 10.

The controller 20 processes image data RGB input from an external source such as a host system so as to be adapted to a size and a resolution of the display panel 10 and supplies the processed image data to the data driver 40. The controller 20 generate a gate control signal GCS and a data control signal DCS based on synchronization signals, for example, a clock signal CLK, a data enable signal DE, a horizontal synchronization signal Hsync, and a vertical synchronization signal Vsync input from the external source, and supplies the generated gate control signal GCS and data control signal DCS to the gate driver 30 and the data driver 40, respectively, thereby controlling the gate driver 30 and the data driver 40.

The controller 20 can be configured to be coupled to various processors, for example, a microprocessor, a mobile processor, an application processor, etc., depending on a type of a device on which the controller is mounted. The controller 20 can be a timing controller.

The host system can be any one of a television (TV) system, a set top box, a navigation system, a personal computer (PC), a home theater system, a mobile device, a wearable device, and a vehicle system.

The controller 20 multiplies an input frame frequency by i and controls an operation timing of each of the gate driver 30 and the data driver 40 using a frame frequency=the input frame frequency×i (i is a positive integer greater than 0) Hz. The input frame frequency is 60 Hz in the National Television Standards Committee (NTSC) scheme and is 50 Hz in the Phase-Alternating Line (PAL) scheme.

The controller 20 generates a signal so that the pixel can operate at various refresh rates. That is, the controller 20 generates operation-related signals such that the pixel can operate in a Variable Refresh Rate (VRR) mode or a refresh rate thereof can be switchable between a first refresh rate and the second refresh rate. For example, the controller 20 can simply change a rate of a clock signal, can generate a synchronization signal to generate a horizontal blank or a vertical blank, or can operate the gate driver 30 in a mask manner such that the pixel P can operate at various refresh rates.

The controller 20 generates, based on the timing signals Vsync, Hsync, and DE received from the host system, the gate control signal GSC for controlling the operation timing of the gate driver 30, and the data control signal DSC for controlling the operation timing of the data driver 40. The controller 20 controls the operation timings of the gate driver 30 and the data driver 40 to synchronize the gate driver 30 and the data driver 40 with each other.

A level shifter converts a voltage level of the gate control signal GSC output from the controller 20 into a gate on voltage VGL and VEL and a gate off voltage VGH and VEH which in turn are supplied to the gate driver 30. The level shifter converts a low level voltage of the gate control signal GSC to a gate low voltage VGL, and converts a high level voltage of the gate control signal GSC to a gate high voltage VGH. The gate control signal GSC includes a start pulse and a shift clock.

The gate driver 30 supplies the scan signal SC to the gate line GL according to the gate control signal GCS supplied from the controller 20. The gate driver 30 can be disposed at one side or each of both opposing sides of the display panel 10 and in a GIP (Gate In Panel) manner.

The gate driver 30 sequentially outputs the gate signal to the plurality of gate lines GL under control of the controller 20. The gate driver 30 can shift the gate signal using a shift register and sequentially supply the shifted gate signal to the gate lines GL.

The gate signal can include the scan signal SC and the light-emission control signal EM in an organic light-emitting display device. The scan signal SC includes a scan pulse swinging between the gate on voltage VGL and the gate off voltage VGH. The light-emission control signal can include a light-emission control signal pulse that swings between the gate on voltage VEL and the gate off voltage VEH.

The scan pulse is synchronized with the data voltage Vdata to select pixels of a line to which the data voltage is to be written. The light-emission control signal EM can define a light-emission time of each of pixels. The light-emission control signal or light-emission signal EM can be a switching signal that turns on each transistor.

The gate driver 30 can include a light-emission control signal driver 31 and at least one scan driver 32.

The light-emission control signal driver 31 outputs the light-emission control signal pulse in response to the start pulse and the shift clock received from the controller 20 and sequentially shifts the light-emission control signal pulse according to the shift clock. The light-emission control signal driver 31 can be simply referred to as a ‘light-emission driver 31’.

Each of the at least one scan driver 32 outputs the scan pulse in response to the start pulse and the shift clock received from the controller 20, and shifts the scan pulse according to a shift clock timing.

The data driver 40 converts the image data RGB into the data voltage Vdata according to the data control signal DCS supplied from the controller 20, and supplies the converted data voltage Vdata to the pixel P through the data line DL.

In FIG. 1, it is illustrated that one data driver 40 is disposed at one side of the display panel 10. However, the number and a position of the data drivers 200 are not limited thereto.

That is, the data driver 40 can be embodied as a plurality of integrated circuits (ICs) which can be disposed at one side of the display panel 10 and can be separately arranged along the one side.

The power supply 50 generates direct current (DC) power necessary for operating a pixel array of the display panel 10 and the display panel driver including the data driver 40 and the gate driver 30, using a DC-DC converter. The DC-DC converter can include a charge pump, a regulator, a buck converter, a boost converter, etc. The power supply 50 receives a DC input voltage applied from the host system and generates DC voltages such as the gate on voltage VGL and VEL, the gate off voltage VGH and VEH, the high-potential driving voltage EVDD, the low-potential driving voltage EVSS, etc. The gate on voltage VGL and VEL and the gate off voltage VGH and VEH are supplied to the level shifter and the gate driver 30. Each of the high-potential driving voltage EVDD and the low-potential driving voltage EVSS is commonly supplied to the pixels.

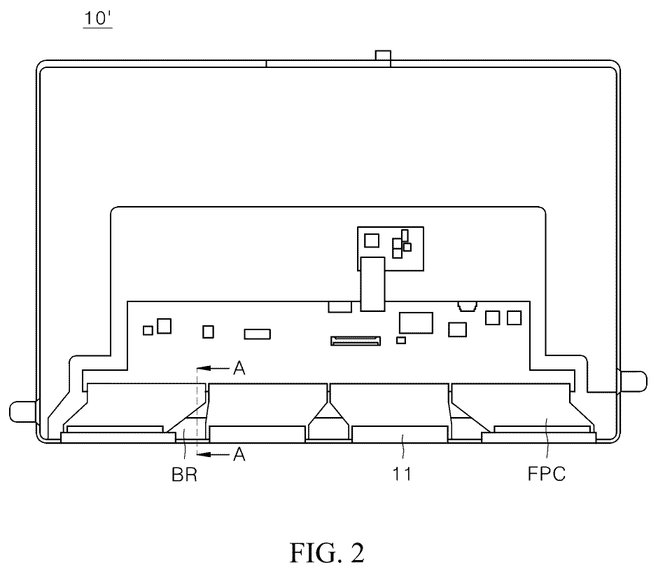

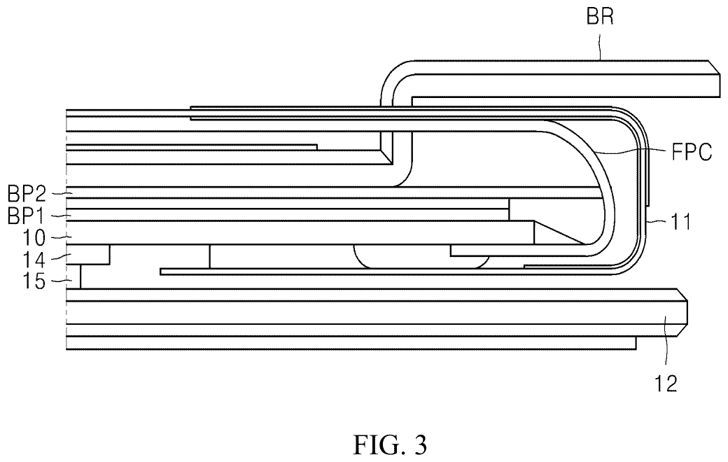

FIG. 2 is a diagram schematically showing a rear surface of a display panel before installation of a bracket fastening plate according to an embodiment of the present disclosure, and FIG. 3 is a cross-sectional view of the display panel according to an embodiment of the present disclosure as cut along a cutting line A-A of FIG. 2.

The display panel 10 according to an embodiment of the present disclosure can include the front surface and the rear surface.

Referring to FIG. 2, the rear surface 10′ of the display panel 10 can include a flexible printed circuit board FPC, a reinforcement member 11, and a bracket BR which are disposed at a bottom thereof and have been bent from the front surface of the display panel 10.

The flexible printed circuit board FPC electrically connects the display panel 10 and the printed circuit board PCB to each other. For example, the flexible printed circuit board FPC has one side in contact with an end of the display panel 10, and the other side which has been bent from the display panel 10 so as to be in contact with a rear surface of the bracket BR, so that the flexible printed circuit board FPC electrically connects the display panel 10 and the printed circuit board PCB to each other.

Referring to FIG. 3, one side of the flexible printed circuit board FPC can be disposed at an end of the front surface of the display panel 10 toward a rear surface of a cover member 12, and the other side thereof can be bent and disposed on the rear surface of the bracket BR.

The reinforcing member 11 serves to reinforce the bending of the flexible printed circuit board FPC so that the bent state thereof is maintained stably. The cover member 12 can be disposed on the front surface of the display panel 10.

A plate BP can be disposed on the rear surface of the display panel 10. The plate BP can include a first plate BP1 and a second plate BP2. The second plate BP2 can be disposed on top of the first plate BP1, or the first plate BP1 can be disposed on top of the second plate BP2. The first plate BP1 and the second plate BP2 can be adhered to each other through an adhesive member. The plate BP includes a metal and plays the role of supporting the display panel 10.

The bracket BR is disposed on a rear surface of the plate BP and serves to support the plate BP.

Referring to FIG. 2, on the rear surface 10′ of the display panel 10, the printed circuit board PCB can be connected to a control board CB through a signal transmission member (STM).

The printed circuit board PCB can be commonly connected to at least one flexible printed circuit board FPC. The printed circuit board PCB can include, for example, a data driving integrated circuit. The printed circuit board PCB according to one embodiment can be electrically connected to the other side of each of the at least one flexible printed circuit board FPC in a film attachment process using an anisotropic conductive film. As each of the at least one flexible printed circuit board FPC has been bent, the printed circuit board PCB can be disposed on a first rear surface edge portion of the display panel 10. The first rear surface edge portion of the display panel 10 can be an area of the rear surface 10′ of the display panel 10 on which the at least one flexible printed circuit board FPC and the printed circuit board PCB are disposed. For example, the first rear surface edge portion of the display panel 10 can be expressed as one side portion of the rear surface 10′ of the display panel 10. The printed circuit board PCB can be located between the control board CB and the bracket BR while being disposed on the rear surface 10′ of the display panel 10.

The signal transmission member STM can transmit various control signals or control data from the control board CB to the printed circuit board PCB, or can transmit various response signals or response data from the printed circuit board PCB to the control board CB.

The control board CB can be disposed on the rear surface 10′ of the display panel 10 and can be connected to the printed circuit board PCB through the signal transmission member STM. The control board CB can include, for example, a timing controller. The control board CB can be connected to a display host system (or a display driving system) through a connector. The control board CB can provide timing synchronization signals and image data supplied from the display host system to the timing controller, and can provide digital pixel data output from the timing controller to the data driving integrated circuit through the signal transmission member STM and the printed circuit board PCB.

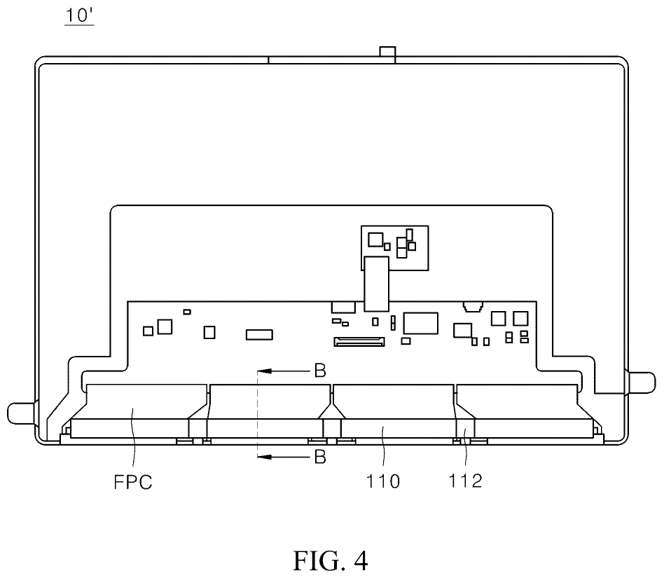

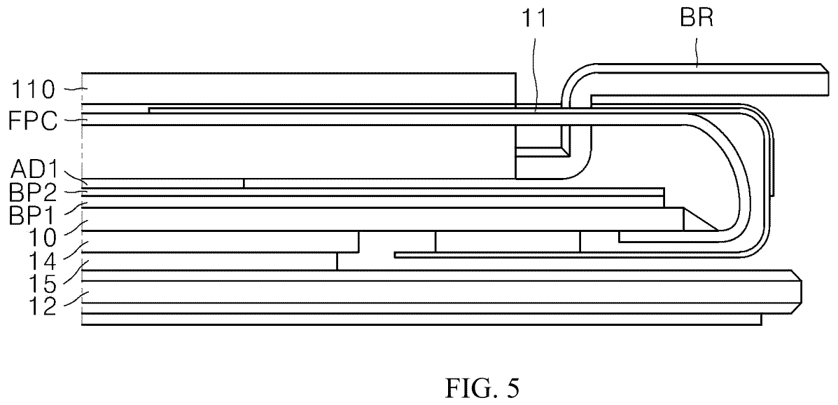

FIG. 4 is a drawing schematically showing a rear surface of the display panel after installation of the bracket fastening plate according to an embodiment of the present disclosure. FIG. 5 is a cross-sectional view of the display panel according to an embodiment of the present disclosure cut along a cutting line B-B in FIG. 4.

The display panel 10 according to an embodiment of the present disclosure can include the front surface and the rear surface.

In FIG. 4 and FIG. 5, the illustration and the description of the printed circuit board PCB, the signal transmission member STM, and the control board CB as shown in FIG. 2 and FIG. 3 can be omitted.

Referring to FIG. 4, on the rear surface 10′ of the display panel 10, a bracket fastening plate 110 can be disposed on a rear surface of the flexible printed circuit board FPC so as to fix the bracket BR.

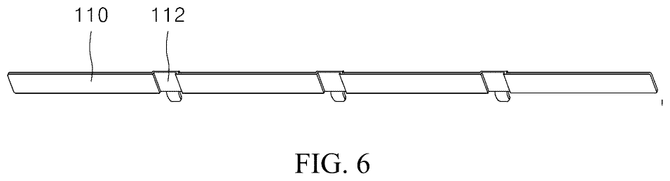

As shown in FIG. 6, the bracket fastening plate 110 can have a constant width and a certain length. FIG. 6 is a diagram showing a shape of the bracket fastening plate according to an embodiment of the present disclosure.

The flexible printed circuit board FPC can include a plurality of flexible printed circuit boards, wherein the other side of each of the plurality of flexible printed circuit boards is bent from an end of the front surface of the display panel 10 so as to be disposed on the rear surface of the bracket BR. As shown in FIG. 5, the bracket fastening plate 110 can be disposed on the flexible printed circuit board FPC disposed on top of the bracket BR, thereby screening a portion of the bracket BR between adjacent ones of the plurality of flexible printed circuit boards, and thus making the bracket BR invisible to the outside.

The bracket fastening plate 110 can have bent protrusions 112 at positions corresponding to positions between adjacent ones of the plurality of flexible printed circuit boards.

Each of the bent protrusions 112 of the bracket fastening plate 110 can be fixedly fitted into each of gaps defined between adjacent ones of the plurality of flexible printed circuit boards.

The bent protrusions 112 of the bracket fastening plate 110 can protrude toward the front surface of the display panel 10, and can be fixedly fitted respectively into the gaps defined between adjacent ones of the plurality of flexible printed circuit boards.

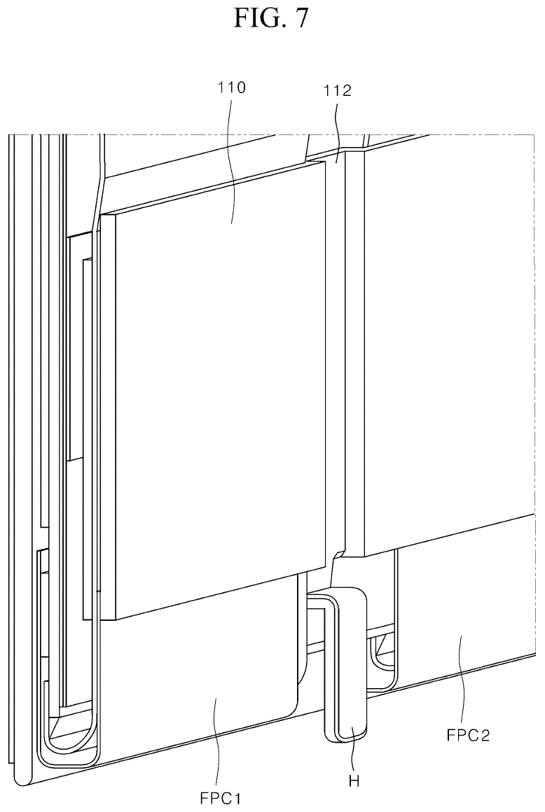

As shown in FIG. 7, the bent protrusion 112 of the bracket fastening plate 110 can be fixedly fitted into a gap defined, for example, between a first flexible printed circuit board FPC1 and a second flexible printed circuit board FPC2, such that the bracket fastening plate 110 can stably fix the bracket BR disposed under the plurality of flexible printed circuit boards. FIG. 7 is a diagram showing an example in which the bracket fastening plate are disposed on the plurality of flexible printed circuit board FPC according to an embodiment of the present disclosure. As shown in FIG. 7, the bracket fastening plate 110 can have a handle H protruding in bent manner from the bent protrusion 112 at the position between adjacent ones of the plurality of flexible printed circuit boards. The handle H is useful when a worker places the bracket fastening plate 110 on the plurality of flexible printed circuit boards FPC and inserts the bent protrusions 112 respectively into the gaps defined between adjacent ones of the plurality of flexible printed circuit boards FPC.

Referring to FIG. 5, an optical adhesive layer 15 can be disposed on the cover member 12, an optical adjustment layer 14 can be disposed on the optical adhesive layer 15, and the display panel 10 can be disposed on the optical adjustment layer 14.

The cover member 12 can be disposed on the display panel 10 and can include a bezel area including a bent area and a front surface area including the display area AA.

The first plate BP1 can be disposed on the display panel 10, the second plate BP2 can be disposed on the first plate BP1, a first adhesive layer AD1 can be disposed on the second plate BP2, and the bracket BR can be disposed on the first adhesive layer AD1.

The flexible printed circuit board FPC can be disposed on the bracket BR, the reinforcing member 11 can be disposed on the flexible printed circuit board FPC, and the bracket fastening plate 110 can be disposed on the reinforcing member 11.

The bracket fastening plate 110 can be bonded to the plurality of flexible printed circuit boards FPC through an adhesive member.

The adhesive member can be composed of at least one or more layers made of at least one of a transparent optical adhesive OCA (Optical Clear Adhesive), a transparent optical resin OCR (Optical Clear Resin), or a pressure sensitive adhesive (PSA).

Referring to FIG. 4, the bracket fastening plate 110 can extend to overlap a first flexible printed circuit board at a position corresponding to one end of the display panel 10 to an n-th flexible printed circuit board at a position corresponding to the other end of the display panel 10 among the plurality of flexible printed circuit boards FPC.

Accordingly, the bracket fastening plate 110 can extend by a length corresponding to a sum of lengths of the first flexible printed circuit board to the n-th flexible printed circuit board.

In a plan view, a dimension in a row direction of the display panel 10 can be larger than a dimension in a column direction of the display panel 10. A dimension in a row direction of the bracket fastening plate 110 can be smaller than the dimension in the row direction of the display panel 10.

The optical adjustment layer (POL) 14 can be disposed on the front surface of the display panel 10 and between the display panel 10 and the cover member 12. A second adhesive member can be disposed between a front surface of the optical adjustment layer 14 and the cover member 12.

The optical adjustment layer 14 can include a polarizing layer POL. The polarizing layer 14 prevents the contrast ratio CR from decreasing due to external light. In the display device 100 according to the present disclosure, the polarizing layer POL that blocks external light incident from the outside is disposed in the transmission direction of the light emitted through the display panel 111 when the OLED panel operates in a driving mode in which the OLED displays an image. Thus, the contrast ratio is improved.

The second adhesive member can include an optical adhesive layer OCA. The optical adhesive layer OCA can have a thickness of, for example, 100 to 300 μm. When the optical adhesive layer OCA has a thickness smaller than 100 μm, the adhesive strength becomes weak, making it difficult to modularize the cover member 12 and the first and second plates BP1 and BP2 with each other. When the optical adhesive layer OCA has a thickness exceeding 300 μm, the display device 100 may not be bent. Therefore, the optical adhesive layer OCA can have the thickness in a range of 100 to 300 μm.

The first and second plates BP1 and BP2 can have a strength equal to or above a predetermined value to supplement the rigidity of the display panel 10. Each of the first and second plates BP1 and BP2 can be made of a plastic material including at least one of, for example, polycarbonate (PC), polyimide (PI), polyethylene naphthalate (PEN), and polyethylene terephthalate (PET).

A connection member can be disposed between the first and second plates BP1 and BP2. The connection member can include a foam tape or a foam pad, or can include a tape with a shock absorbing function or a double-sided tape with conductivity. For example, double-sided conductive tape can include an upper adhesive layer, a lower adhesive layer, and a conductive layer between the upper adhesive layer and the lower adhesive layer. The adhesive layer can include a conductive material.

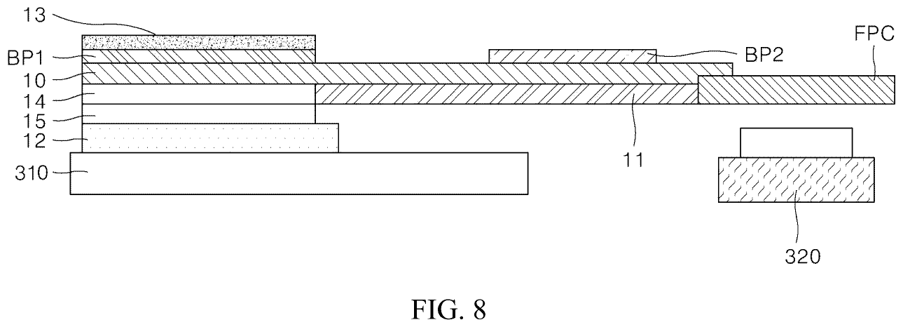

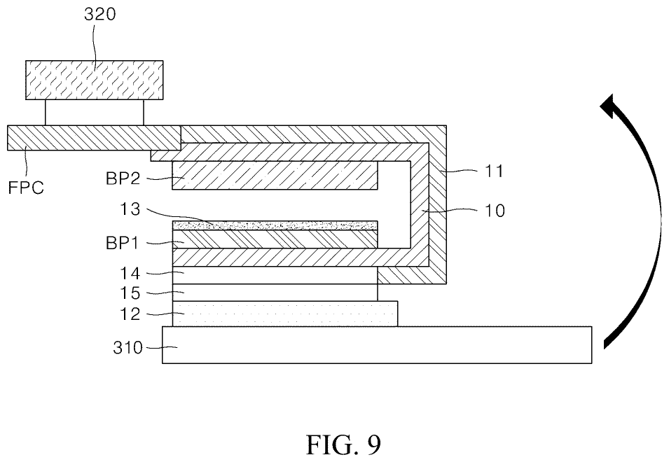

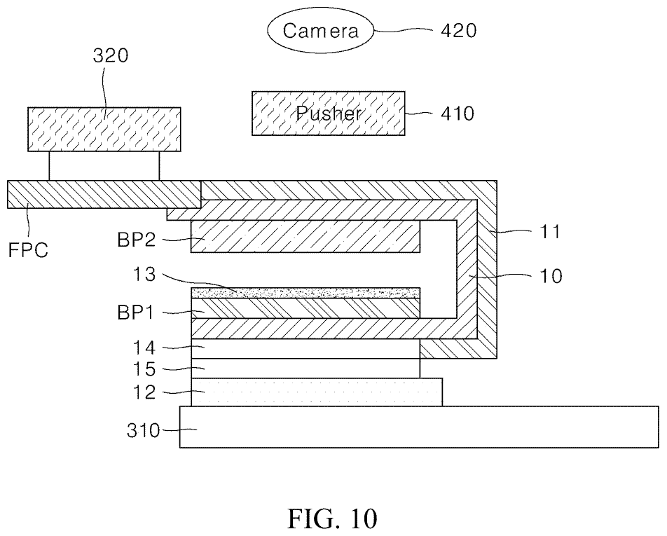

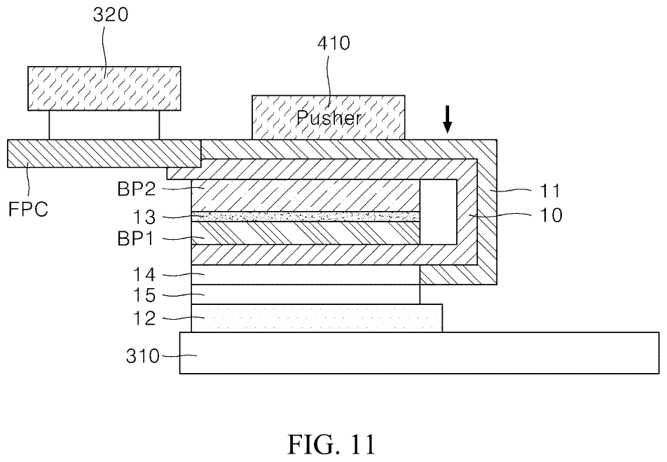

FIG. 8 is a diagram showing a FPC suctioning process before bending the display panel according to an embodiment of the present disclosure. FIG. 9 is a diagram showing a process of bending after suctioning the display panel and the FPC according to an embodiment of the present disclosure. FIG. 10 is a diagram showing a process of aligning the display panel according to an embodiment of the present disclosure. FIG. 11 is a diagram showing a process of physically bonding the first plate and the second plate to each other according to an embodiment of the present disclosure.

Referring to FIGS. 8 to 11, a display module of the display device according to an embodiment of the present disclosure can be disposed on a stage 310. In this regard, in the display module, the optical adhesive layer 15 and the optical adjustment layer 14 can be sequentially stacked on the cover member 12. The display panel 10 can be disposed on the optical adjustment layer 14.

The first plate BP1 can be disposed on one side of the display panel 10, and a connection member 13 can be disposed on the first plate BP1.

Furthermore, the second plate BP2 can be disposed on the other side of the display panel 10.

The reinforcement member 11 can be disposed under the display panel 10. The flexible printed circuit board FPC can be connected to the other end of the display panel 10 and the other end of reinforcement member 11.

Suctioning means (or unit) 320 can be disposed under the flexible printed circuit board FPC.

Therefore, in a manufacturing process of the display device 100 according to an embodiment of the present disclosure, the sectioning means 320 operates to suction the flexible printed circuit board FPC to bend the display panel 10.

Referring to FIG. 9, in the manufacturing process of the display device according to an embodiment of the present disclosure, after adsorbing the flexible printed circuit board FPC, the sectioning means 320 can be displaced into a position on top of the connection member 13 such that the display panel 10 is bent.

Accordingly, the second plate BP2 is positioned on top of the first plate BP1.

At this time, the bent portion of the display panel 10 is located on top of the second plate BP2, and the bent portion of the reinforcement member 11 is located on top of the bent portion of the display panel 10.

Referring to FIG. 10, in the manufacturing process of the display device according to an embodiment of the present disclosure, a pusher 410 410 and a camera 420 can be placed on top of the display panel 10 and the reinforcement member 11 so as to overlap the second plate BP2 and can be used to correctly align the display panel 10.

Then, an align key can be read using the camera 420, and the first plate BP1 and the second plate BP2 can be aligned with each other using the align key so as to overlap each other exactly.

Referring to FIG. 11, in the manufacturing process of the display device according to an embodiment of the present disclosure, after the alignment has been completed, the pusher 410 moves downward to press the bent portion of each of the reinforcement member 11 and the display panel 10.

Accordingly, the second plate BP2 moves downwards and contacts the first plate BP1 under a downward pressure of the pusher 410, and thus the first plate BP1 and the second plate BP2 are physically bonded to each other.

The first plate BP1 and the second plate BP2 are bonded to each other through the connection member 13.

The connection member 13 can be a member that adheres and fixes the first plate BP1 and the second plate BP2 to each other. The connection member 13 can include a material with strong adhesive force or a double-sided tape. The connection member 13 can be composed of at least one or more layers made of at least one of a transparent optical adhesive OCA (Optical Clear Adhesive), a transparent optical resin OCR (Optical Clear Resin), or a pressure sensitive adhesive (PSA).

In one example, the connection member 13 can include a foam tape or a foam pad, or can include a tape with a shock absorbing function or a double-sided tape with conductivity. For example, double-sided conductive tape can include an upper adhesive layer, a lower adhesive layer, and a conductive layer between the upper adhesive layer and the lower adhesive layer. The adhesive layer can include a conductive material.

As described above, according to an embodiment of the present disclosure, the display device can be realized in which the plate disposed on the rear surface of the display panel can be supported by the bracket, and the flexible printed circuit board FPC can be disposed on the rear surface of the bracket, and the bracket fastening plate disposed on the rear surface of the flexible printed circuit board FPC can fix the bracket.

Although embodiments of the present disclosure have been described with reference to the accompanying drawings, the present disclosure is not limited to the above embodiments, but can be implemented in various different forms. A person skilled in the art can appreciate that the present disclosure can be practiced in other concrete forms without changing the technical spirit or essential characteristics of the present disclosure. Therefore, it should be appreciated that the embodiments as described above is not restrictive but illustrative in all respects.

What is claimed is:

1. A display device comprising:
a display panel including a front surface and a rear surface;
a cover member disposed on the front surface of the display panel;
a plate disposed on the rear surface of the display panel;
a bracket disposed on a rear surface of the plate so as to support the plate;
a flexible printed circuit board having one end disposed on one end of the front surface of the display panel so as to face a rear surface of the cover member, wherein the flexible printed circuit board is bent so that another end of the flexible printed circuit board is disposed on a rear surface of the bracket; and
a bracket fastening plate disposed on a rear surface of the flexible printed circuit board so as to fasten the bracket.

2. The display device of claim 1, wherein the bracket fastening plate has a constant width and a predetermined length.

3. The display device of claim 1, wherein the flexible printed circuit board includes a plurality of flexible printed circuit boards arranged in a row direction,
wherein each of the plurality of flexible printed circuit boards has one end of the front surface of the display panel so as to face the rear surface of the cover member,
wherein each of the plurality of flexible printed circuit boards is bent so that the another end of the corresponding flexible printed circuit board is disposed on the rear surface of the bracket, and
wherein the bracket fastening plate has bent protrusions respectively formed at positions corresponding to positions between adjacent ones of the plurality of flexible printed circuit boards.

4. The display device of claim 3, wherein the bent protrusions of the bracket fastening plate are fixedly fitted respectively into gaps between the adjacent ones of the plurality of flexible printed circuit boards.

5. The display device of claim 4, wherein each of the bent protrusions of the bracket fastening plate protrudes toward the front surface of the display panel, and is fixedly fitted into one of the gaps between the adjacent ones of the plurality of flexible printed circuit boards.

6. The display device of claim 3, wherein the bracket fastening plate is bonded to the plurality of flexible printed circuit boards through an adhesive member.

7. The display device of claim 3, wherein the plurality of flexible printed circuit boards include first to n-th flexible printed circuit boards, where n is a real number, and
wherein the bracket fastening plate extends to overlap the first flexible printed circuit board at a position corresponding to one end of the display panel to the n-th flexible printed circuit board at a position corresponding to another end of the display panel.

8. The display device of claim 7, wherein the bracket fastening plate extends by a length corresponding to a sum of lengths of the first flexible printed circuit board to the n-th flexible printed circuit board.

9. The display device of claim 1, wherein in a plan view of the display device, a dimension in a row direction of the display panel is larger than a dimension in a column direction of the display panel, and
wherein a dimension in a row direction of the bracket fastening plate is smaller than the dimension in the row direction of the display panel.

10. The display device of claim 1, wherein an optical adjustment layer is disposed on the front surface of the display panel between the display panel and the cover member, and
wherein a second adhesive member is disposed between a front surface of the optical adjustment layer and the cover member.
